(19) United States
(12) Patent Application Publication
(10) Pub. No.: US 2025/0109970 A1
(43) Pub. Date: Apr. 3, 2025

(54) OPTICAL SENSORS HAVING AN ABSENCE OF GUARD STRUCTURES BETWEEN ADJACENT PHOTODIODES

(71) Applicant: Apple Inc., Cupertino, CA (US)

(72) Inventors: Anand K. Chamakura, San Jose, CA (US); Dong Zheng, Los Altos, CA (US); Mieczyslaw M. Dabrowski, San Francisco, CA (US); David D. Dashevsky, San Jose, CA (US)

(21) Appl. No.: 18/671,832

(22) Filed: May 22, 2024

Related U.S. Application Data
(60) Provisional application No. 63/541,244, filed on Sep. 28, 2023.

(51) Int. Cl. G01D 5/347

(52) U.S. Cl. CPC G01D 5/34715

(57) ABSTRACT

An electronic device includes a shared epitaxial structure, an array of photodiodes formed in the shared epitaxial structure, and a readout circuit. The array of photodiodes is disposed between a first axis and a second axis, with the second axis orthogonal to the first axis. The array of photodiodes has an absence of guard structures between adjacent photodiodes. The readout circuit is electrically connected to the array of photodiodes and operable to read out values for different photodiodes or different subsets of photodiodes in the array of photodiodes.

### CROSS-REFERENCE TO RELATED APPLICATION

This application is a nonprovisional and claims the benefit under 35 U.S.C. § 1.119(e) of U.S. Provisional Patent Application No. 63/541,244, filed Sep. 28, 2023, the contents of which are incorporated herein by reference as if fully disclosed herein.

### FIELD

The described embodiments generally relate to optical sensors and, more particularly, to optically sensing movement of a light spot, light stripe, or other shape or pattern of light across an array of photodiodes.

### BACKGROUND

Many of today's devices include a user-operable input device, such as a button, crown, dial, or knob. Some of the devices that may include such an input device include wearable devices (e.g., wrist-worn devices, headsets, or earphones), a game controller, a dashboard, or any other type of device (e.g., another type of portable, wearable, movable, or stationary device). Some input devices may only rotate or translate. Other input devices may both rotate and translate. A device that includes a rotatable and/or translatable input device needs a way to sense when the input device has been rotated or translated. Sometimes this may be done using an optical sensor.

An optical sensor may also be used to track or determine the position of a light spot, light stripe, or other shape or pattern of light in other contexts, such as for force sensing or atomic force microscopy.

### SUMMARY

Embodiments of the systems, devices, methods, and apparatus described in the present disclosure employ optical sensing to track or determine the position of a light spot, light stripe, or other shape or pattern of light. In some embodiments, the optical sensors may be used to detect (or track) translational and/or rotational movements of a shaft, such as a shaft that forms part of an input device.

In a first aspect, the present disclosure describes an electronic device. The electronic device may include a shared epitaxial structure, an array of photodiodes formed in the shared epitaxial structure, and a readout circuit. The array of photodiodes may be disposed between a first axis and a second axis, with the second axis orthogonal to the first axis. The array of photodiodes may have an absence of guard structures between adjacent photodiodes. The readout circuit may be electrically connected to the array of photodiodes and may be operable to read out values for different photodiodes or different subsets of photodiodes in the array of photodiodes.

In a second aspect, the present disclosure describes another electronic device. The electronic device may include a shared epitaxial structure, an array of photodiodes formed in the shared epitaxial structure, a readout circuit, and a control circuit. The array of photodiodes may have an absence of guard structures between adjacent photodiodes. The readout circuit may be electrically connected to the array of photodiodes and may be operable to read out values for a set of channels defined by the photodiodes in the array of photodiodes. The control circuit may be operable to configure the readout circuit in one or more modes of operation. Each mode of operation in the one or more modes of operation may define at least one of a number of channels in the set of channels, or a number of photodiodes per channel in the set of channels.

In a third aspect, the present disclosure describes another electronic device. The electronic device may include a housing, a crown, a light source, and an optical sensor. The crown may have a shaft. The shaft may extend through the housing and have a set of features disposed around the shaft. The light source may be positioned within the housing and may be configured to emit light toward the shaft. The optical sensor may be positioned within the housing and may be configured to receive reflections of the emitted light from the set of features. The optical sensor may include a shared epitaxial structure and an array of photodiodes formed in the shared epitaxial structure. The array of photodiodes may have an absence of guard structures between adjacent photodiodes.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIGS. 1A and 1B show an example electronic device;

FIG. 2 shows an elevation of a crown module;

FIG. 3A shows a plan view of an example optical sensor, and FIG. 3B shows a cross-section of the optical sensor along cutline 3B-3B of FIG. 3A;

FIG. 3C shows an example output of the optical sensor shown in FIGS. 3A and 3B, in response to a light spot moving from left to right across the optical sensor;

FIG. 4 shows an alternative example readout circuit for an optical sensor such as the optical sensor of FIGS. 3A and 3B;

FIG. 5 shows another alternative example readout circuit for an optical sensor such as the optical sensor of FIGS. 3A and 3B;

FIGS. 6A and 6B show another alternative example readout circuit for an optical sensor such as the optical sensor of FIGS. 3A and 3B;

FIGS. 7A and 7B show another alternative example readout circuit for an optical sensor such as the optical sensor of FIGS. 3A and 3B;

FIGS. 8A and 8B illustrate an example readout plan for an optical sensor such as the optical sensor of FIGS. 3A and 3B;

FIGS. 9A and 9B illustrate another example readout plan for an optical sensor such as the optical sensor of FIGS. 3A and 3B;

FIG. 10 shows a plan view of another example optical sensor; and

FIG. 11 shows an example block diagram of an electronic device.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

When tracking the intensity of a light spot or light stripe across an array of photodiodes or other optical elements, there is a tracking error every time the light spot or light stripe crosses from one pixel to an adjacent pixel. The tracking error is, in part, a result of guard structures that are disposed between adjacent pixels. Guard structures are used to electrically isolate the pixels in an array of pixels from adjacent pixels. However, guard structures also typically optically isolate one pixel from another, thereby forming a light-insensitive grid (i.e., optically dead areas) within an array of pixels.

The systems, devices, methods, and apparatus described herein remove optically dead areas within an array of pixels by removing the guard structures between adjacent photodiodes. That is, each photodiode may be formed as a photodiode island within a shared epitaxial structure, without there being any guard structures to electrically isolate the photodiodes.

In some embodiments, an optical sensor including one of the arrays of photodiodes described herein may be used to track rotation and/or translation of a crown or other input device.

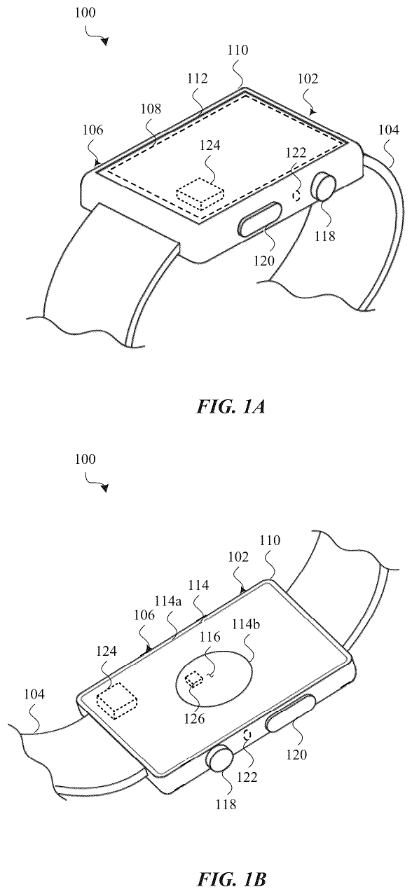

These and other systems, devices, methods, and apparatus are described with reference to FIGS. 1A-11. However, those skilled in the art will readily appreciate that the detailed description given herein with respect to these figures is for explanatory purposes only and should not be construed as limiting.

Directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration and is not always limiting. The directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

FIGS. 1A and 1B show an example of a device 100 (an electronic device) that may include an assembly for optically sensing translational and/or rotational shaft movements. The device's dimensions and form factor, and inclusion of a band 104 (e.g., a wrist band), suggest that the device 100 is an electronic watch, fitness monitor, or health diagnostic device. However, the device 100 could alternatively be any type of wearable device, including earphones or a headset. FIG. 1A shows a front isometric view of the device 100, and FIG. 1B shows a back isometric view of the device 100.

The device 100 may include a body 102 (e.g., a watch body). The body 102 may include an input or selection device, such as a crown 118 or a button 120. A band 104 may be attached to a housing 106 of the body 102 and may be used to attach the body 102 to a body part (e.g., an arm, wrist, leg, ankle, or waist) of a user. The body 102 may include a housing 106 that at least partially surrounds a display 108. In some embodiments, the housing 106 may include a sidewall 110, which sidewall 110 may support a front cover 112 (FIG. 1A) and/or a back cover 114 (FIG. 1B). The front cover 112 may be positioned over the display 108 and may provide a window through which the display 108 may be viewed. In some embodiments, the display 108 may be attached to (or abut) the sidewall 110 and/or the front cover 112. In alternative embodiments of the device 100, the display 108 may not be included and/or the housing 106 may have an alternative configuration.

The display 108 may include one or more light-emitting elements including, for example, light-emitting elements that define a light-emitting diode (LED) display, organic LED (OLED) display, liquid crystal display (LCD), electroluminescent (EL) display, or other type of display. In some embodiments, the display 108 may include, or be associated with, one or more touch and/or force sensors that are configured to detect a touch and/or a force applied to a surface of the front cover 112.

In some embodiments, the sidewall 110 of the housing 106 may be formed using one or more metals (e.g., aluminum or stainless steel), polymers (e.g., plastics), ceramics, or composites (e.g., carbon fiber). The front cover 112 may be formed, for example, using one or more of glass, a crystal (e.g., sapphire), or a transparent polymer (e.g., plastic) that enables a user to view the display 108 through the front cover 112. In some cases, a portion of the front cover 112 (e.g., a perimeter portion of the front cover 112) may be coated with an opaque ink to obscure components included within the housing 106. In some cases, all of the exterior components of the housing 106 may be formed from a transparent material, and components within the device 100 may or may not be obscured by an opaque ink or opaque structure within the housing 106.

The back cover 114 may be formed using the same material(s) that are used to form the sidewall 110 or the front cover 112. In some cases, the back cover 114 may be part of a monolithic element that also forms the sidewall 110. In other cases, and as shown, the back cover 114 may be a multi-part back cover, such as a back cover having a first back cover portion 114a attached to the sidewall 110 and a second back cover portion 114b attached to the first back cover portion 114a. The second back cover portion 114b may in some cases have a circular perimeter and an arcuate exterior surface 116 (i.e., an exterior surface 116 having an arcuate profile).

The front cover 112, back cover 114, or first back cover portion 114a may be mounted to the sidewall 110 using fasteners, adhesives, seals, gaskets, or other components. The second back cover portion 114b, when present, may be mounted to the first back cover portion 114a using fasteners, adhesives, seals, gaskets, or other components.

A display stack or device stack (hereafter referred to as a “stack”) including the display 108 may be attached (or abutted) to an interior surface of the front cover 112 and extend into an interior volume of the device 100. In some cases, the stack may include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 112 (e.g., to a display surface of the device 100).

In some cases, a force sensor (or part of a force sensor system) may be positioned within the interior volume below and/or to the side of the display 108 (and in some cases within the device stack). The force sensor (or force sensor system) may be triggered in response to the touch sensor detecting one or more touches on the front cover 112 (or a location or locations of one or more touches on the front cover 112) and may determine an amount of force associated with each touch, or an amount of force associated with the collection of touches as a whole. The force sensor (or force sensor system) may alternatively trigger operation of the touch sensor (or touch sensor system) or may be used independently of the touch sensor (or touch sensor system).

The device 100 may include various sensors. In some embodiments, the device 100 may have a port 122 (or set of ports) on a side of the housing 106 (or elsewhere), and an ambient pressure sensor, ambient temperature sensor, internal/external differential pressure sensor, gas sensor, particulate matter concentration sensor, or air quality sensor may be positioned in or near the port(s) 122.

In some cases, one or more skin-facing sensors 126 may be included within the device 100. The skin-facing sensor(s) 126 may emit or transmit signals through the housing 106 (or back cover 114) and/or receive signals or sense conditions through the housing 106 (or back cover 114). For example, in some embodiments, one or more such sensors may include a number of light sources (e.g., visible light and/or IR emitters) and/or a number of optical sensors (e.g., visible light and/or IR sensors, such as any of the optical sensors described herein). The sensors may be used, for example, to acquire biological information from the wearer or user of the device 100 (e.g., a heart rate, respiration rate, blood pressure, blood flow rate, blood oxygenation, blood glucose level, and so on), or to determine a status of the device 100 (e.g., whether the device 100 is being worn or a tightness of the device 100).

The device 100 may include circuitry 124 (e.g., a processor and/or other components) configured to determine or extract, at least partly in response to signals received directly or indirectly from one or more of the device's sensors, and by way of example, biological parameters of the device's user, an input provided by the user, a status of the device 100 or its environment, and/or a position (or other aspects) of objects, particles, surfaces, or a user. The biological parameters may include, for example, a biometric, heart rate, respiration rate, blood pressure, blood flow rate, blood oxygenation, blood glucose level, and so on. In some embodiments, the circuitry 124 may be configured to convey the determined or extracted parameters, inputs, or statuses via an output device of the device 100. For example, the circuitry 124 may cause the indication(s) to be displayed on the display 108, indicated via audio or haptic outputs, transmitted via a wireless communications interface or other communications interface, and so on. The circuitry 124 may also or alternatively maintain or alter one or more settings, functions, or aspects of the device 100, including, in some cases, what is displayed on the display 108.

In some embodiments, one of the assemblies described herein for optically sensing translational and/or rotational shaft movements may be associated with the crown 118. The assembly may be used, for example, to determine whether the crown 118 has been rotated, how much the crown 118 has been rotated, how fast the crown 118 has been rotated, whether the crown 118 has been pressed (or pulled), and so on.

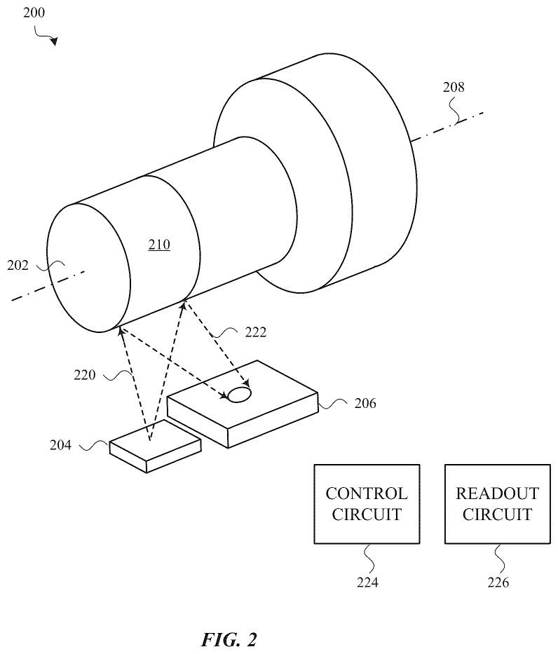

FIG. 2 shows an example assembly 200 including a shaft 202, a light source 204, and an optical sensor 206. In some embodiments, the shaft 202 may be a shaft of a rotatable and translatable input device, such as a shaft of a crown, button, dial, or knob. The input device may be provided on a wearable device (e.g., a wrist-worn device, headset, or earphones), a game controller, a dashboard, or any other type of device (e.g., another type of portable, wearable, movable, or stationary device). In some embodiments, the shaft 202 may be a shaft of the crown described with reference to FIGS. 1A and 1B. In some embodiments, the shaft 202 may be a shaft of a machine or engine.

The shaft 202 may be supported, at least in part, by a housing through which the shaft 202 extends (e.g., the housing of the device described with reference to FIGS. 1A and 1B), or by a support member, sleeve, or bearing through which the shaft 202 extends, or by a support member that cradles or otherwise supports the shaft 202. The light source 204 and optical sensor 206 may be supported by the same housing that supports the shaft 202, or by a different housing, or by a printed circuit board, flexible circuit, or other structure to which the light source 204 and optical sensor 206 are attached.

The shaft 202 (which in some cases may be part of an input device) may be rotatable and translatable with respect to an axis of rotation 208. For example, the shaft 202 may rotate about the axis of rotation 208 and translate along the axis of rotation 208. The shaft 202 may have a circumference and a set of features that define an optical encoder pattern 210 (e.g., an engineered optical surface) or random imperfections around the circumference. In some embodiments, the features of the optical encoder pattern 210 may include a number of light and dark stripes disposed around the circumference of the shaft, with each stripe being parallel to the axis of rotation 208. In some embodiments, the stripes may include stripes formed of the same material, but at different orientations or having different surface treatments.

The light source 204 and optical sensor 206 may be provided as part of a module but may alternatively be separately provided.

The light source 204 may be configured (e.g., positioned and oriented) to emit light 220 toward the optical encoder pattern 210. In some embodiments, the light 220 may include infrared (IR) light, though the light may additionally, or alternatively, include other wavelengths of light. In some embodiments, the light source 204 may include a wide angle and incoherent optical emitter, such as a light-emitting diode (LED), though the light source 204 may also include a laser diode or other type of optical emitter.

The optical sensor 206 may be configured (e.g., positioned and oriented) to receive reflections 222 of the emitted light, from the features of the optical encoder pattern 210, and generate an irradiance pattern in response to the reflections 222. The optical sensor 206 may include a two-dimensional (2D) array of photodiodes, or pixels. Movements or changes in the irradiance pattern along a first dimension may be primarily used to determine a rotation of the shaft 202. Movements or changes in the irradiance pattern along a second dimension may be primarily used to determine a translation of the shaft 202.

In some embodiments, a control circuit 224 may be operable to configure a readout circuit 226 of the optical sensor 206 to operate in accordance with one or more modes of operation. The one or more modes of operation may define, for example, a first number of channels having different axes parallel to the axis of rotation 208 of the shaft 202, and a second number of channels having different axes perpendicular to the axis of rotation 208 of the shaft 202.

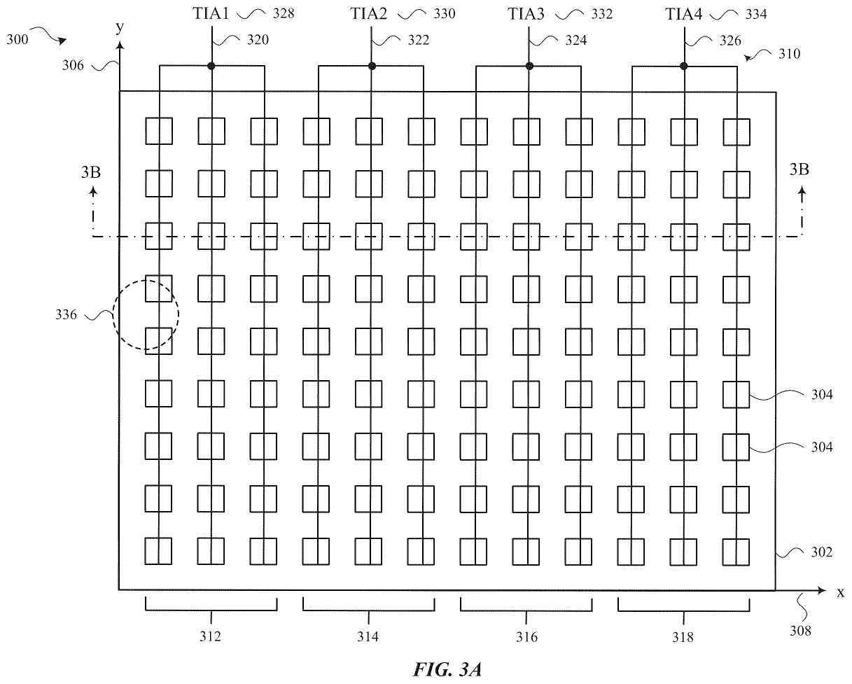

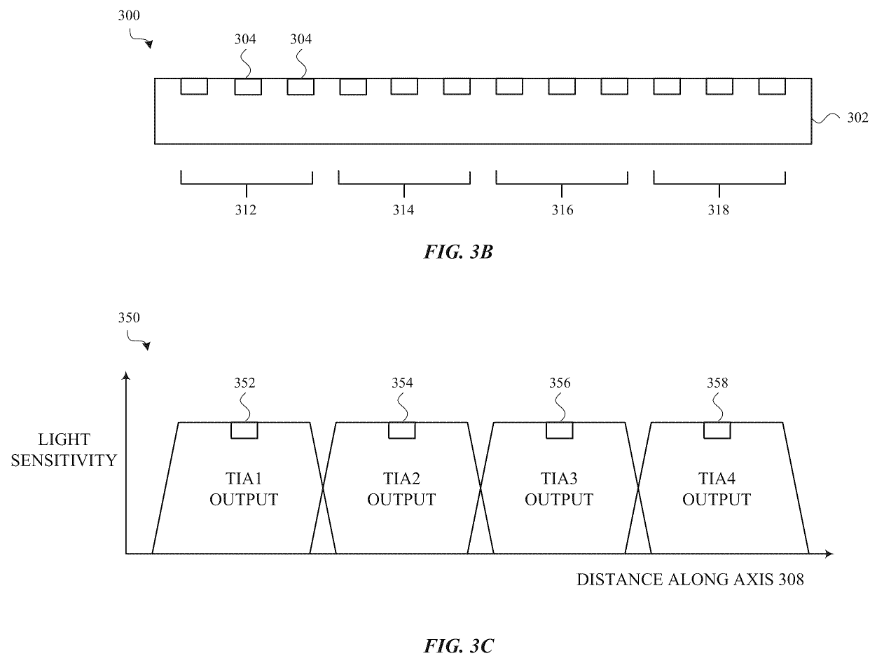

FIGS. 3A-10 describe various optical sensors that may be used for the optical sensor 206.

FIG. 3A shows a plan view of an example optical sensor 300, and FIG. 3B shows a cross-section of the optical sensor 300 along cutline 3B-3B of FIG. 3A. The optical sensor 300 may be used, for example, in the electronic device described with reference to FIGS. 1A and 1B or the crown module described with reference to FIG. 2.

The optical sensor 300 includes an epitaxial structure 302 that is shared by an array of photodiodes 304. The array of photodiodes 304 may be disposed between a first axis 306 (e.g., a y-axis) and a second axis 308 (e.g., an x-axis, orthogonal to the y-axis). In alternative embodiments, the photodiodes 304 may be arranged in different ways, such as in concentric rings or pseudo-randomly. The photodiodes 304 may be constructed using various materials, and may be constructed in accordance with various techniques, to be sensitive to one or more types of light (where light is defined herein to include visible and non-visible types of electromagnetic radiation). In some examples, the photodiodes 304 may only be sensitive to infrared (IR) light. Alternatively, and depending on the application, the photodiodes 304 may only be sensitive to shortwave infrared (SWIR) light, or only to near infrared (NIR) light, or only to a range of visible light (e.g., red light or green light), or to a range of wavelengths that encompasses different types of light.

The array of photodiodes 304 is characterized by an absence of guard structures (e.g., an absence of shallow trench isolation (STI), deep trench isolation (DTI), or other electrical isolation) between adjacent photodiodes 304. That is, each photodiode 304 may be formed as a photodiode island within the shared epitaxial structure 302 (e.g., as a diode structure formed by one or more wells within the shared epitaxial structure 302), without there being any guard structures to electrically isolate a photodiode 304 from adjacent photodiodes 304. Although the absence of guard structures may result in some amount of electrical crosstalk between the photodiodes 304, the absence of guard structures removes a source of optical isolation between the photodiodes 304, which can enable improved tracking of a light spot (or spots), light stripe (or stripes), or other types of light or light patterns across the array of photodiodes 304. Also, downstream processing to account for crosstalk between the photodiodes 304 (or channels defined by subsets of the photodiodes 304) may be easier to account for than discontinuities in light sensitivity between photodiodes 304 (or channels defined by subsets of the photodiodes 304).

Various types of readout circuits may be electrically connected to the array of photodiodes 304, with each type of readout circuit being operable to read out values for different photodiodes 304 (e.g., individual photodiodes 304) or different subsets of photodiodes 304. By way of example, FIG. 3A shows a readout circuit 310 that is operable to read out values for different subsets 312, 314, 316, 318 of photodiodes 304 extending parallel to the first axis 306 (although the different subsets 312, 314, 316, 318 of photodiodes 304 also extend parallel to the second axis 308, but need not; alternatively, subsets of photodiodes could be defined such that the subsets only extend parallel to the second axis 308). Each subset 312, 314, 316, 318 of photodiodes 304 may represent a respective channel in a set of channels of the optical sensor 300.

The readout circuit 310 includes a first set of conductive traces 320 that electrically connect to a first three columns of photodiodes 304, a second set of conductive traces 322 that electrically connect to a second three columns of photodiodes 304, a third set of conductive traces 324 that electrically connect to a third three columns of photodiodes 304, and a fourth set of conductive traces 326 that electrically connect to a fourth three columns of photodiodes 304. As shown in FIG. 3B, each of the photodiodes 304 may share a common cathode. Each set of conductive traces 320, 322, 324, 326 may electrically connect a respective subset 312, 314, 316, 318 of photodiodes 304 to a respective amplifier circuit 328, 330, 332, 334 (e.g., transimpedance amplifiers TIA1, TIA2, TIA3, and TIA4). Alternatively, a set of switches may electrically connect one set of conductive traces 320, 322, 324, 326 at a time to a shared amplifier circuit.

An example output of the optical sensor 300 (and more particularly, an example output of the readout circuit 310), in response to a light spot 336 moving from left to right across the optical sensor 300, is shown in FIG. 3C. FIG. 3C shows a graph 350 of distance along the second axis 308 versus a light sensitivity of each readout channel 352, 354, 356, 358, with the readout channels 352, 354, 356, 358 corresponding to respective ones of the subsets 312, 314, 316, 318 of photodiodes 304.

Each of the channels 352, 354, 356, 358 has a light sensitivity that rises as the light spot 336 begins to illuminate the photodiodes 304 associated with the channel, plateaus while the light spot's illumination is entirely over the photodiodes 304 associated with the channel, and falls at or about the time the light spot 336 begins to illuminate the photodiodes 304 associated with a next channel. Although this results in some amount of electrical crosstalk between the channels 352, 354, 356, 358, there are no optical dead zones and a more uniform light sensitivity within the array of photodiodes 304.

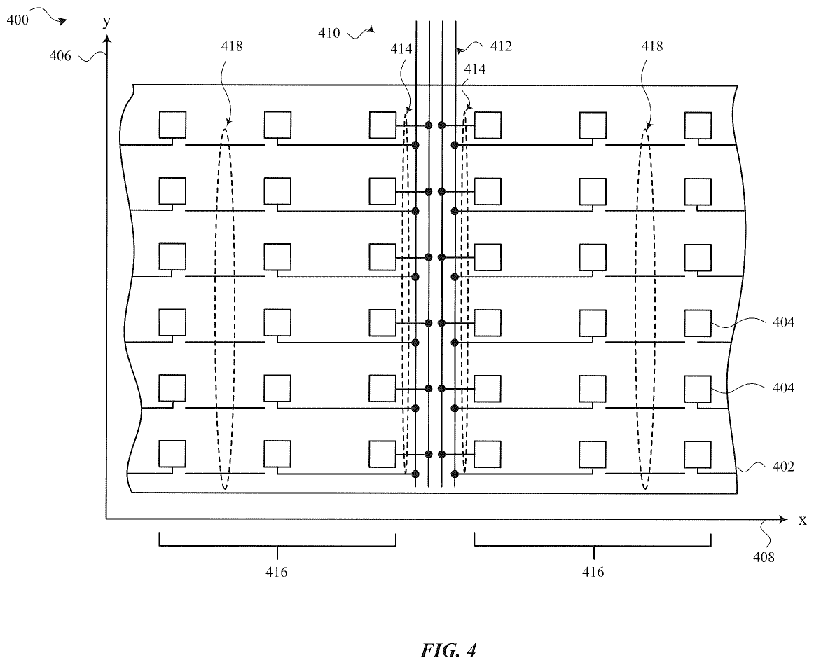

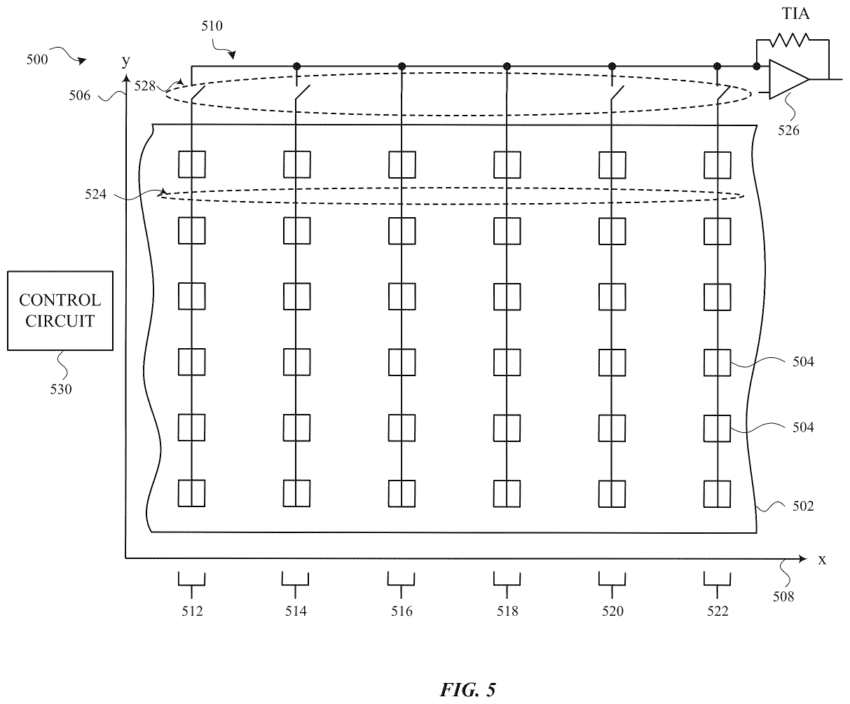

FIG. 4 shows an alternative example readout circuit for an optical sensor such as the optical sensor described with reference to FIGS. 3A and 3B. In particular, FIG. 4 shows an optical sensor 400 having an array of photodiodes 404 formed on a shared epitaxial structure 402, without guard structures between adjacent photodiodes 404. The array of photodiodes 404 may be disposed between a first axis 406 (e.g., a y-axis) and a second axis 408 (e.g., an x-axis, orthogonal to the y-axis).

A readout circuit 410 may be electrically connected to the array of photodiodes 404. The readout circuit 410 may include a first set of conductive traces 412 oriented parallel to the first axis 406. The conductive traces of the first set of conductive traces 412 may extend from within the array of photodiodes 404 to outside (e.g., adjacent or under) the array of photodiodes 404. For example, the conductive traces of the first set of conductive traces 412 may extend between individual ones or subsets of photodiodes 404 and one or more amplifier circuits, with the conductive traces in the first set of conductive traces 412 being directly coupled or switchably coupled to the amplifier circuits (not shown). The readout circuit 410 may also include a second set of conductive traces 414 oriented parallel to the second axis 408. The conductive traces in the second set of conductive traces 414 may electrically connect each photodiode 404 to a particular conductive trace in the first set of conductive traces 412. By way of example, multiple photodiodes 404 are electrically connected to each conductive trace of the first set of conductive traces 412 by a respective conductive trace of the second set of conductive traces 414.

By way of example, the first set of conductive traces 412 is shown to be routed between different subsets 416 of photodiodes 404 corresponding to different readout channels. Although only one group of conductive traces in the first set of conductive traces 412 is shown, the first set of conductive traces 412 may include multiple different groups of conductive traces, with each group of conductive traces in the first set of conductive traces 412 being routed between different subsets 416 of photodiodes 404 corresponding to different readout channels. In some cases, this may limit discontinuities in the light sensitivity of the array of photodiodes 404 to regions between different channels. In alternative embodiments, the conductive traces in the first set of conductive traces 412 may be equally distributed over the array of photodiodes 404.

To provide a uniform light sensitivity to light that passes over the optical sensor 400 from left to right, the optical sensor 400 may include a set of dummy conductive traces 418. Each dummy conductive trace in the set of dummy conductive traces 418 may be oriented parallel to the second axis 308 and be disposed inline with one or more conductive traces in the second set of conductive traces 414.

In a light tracking application in which a light spot moves in a predetermined direction, the conductive traces 412, 414 may more generally be oriented in any way that minimizes the number of conductive traces that the light spot has to cross as it moves across the array of photodiodes 404.

FIG. 5 shows another alternative example readout circuit for an optical sensor such as the optical sensor described with reference to FIGS. 3A and 3B. In particular, FIG. 5 shows an optical sensor 500 having an array of photodiodes 504 formed on a shared epitaxial structure 502, without guard structures between adjacent photodiodes 504. The array of photodiodes 504 may be disposed between a first axis 506 (e.g., a y-axis) and a second 508 (e.g., an x-axis, orthogonal to the y-axis).

A readout circuit 510 may be electrically connected to the array of photodiodes 504 and may be operated to read out values for different subsets 512, 514, 516, 518, 520, 522 of photodiodes 504 in the array of photodiodes 504. The readout circuit 510 may include a set of conductive traces 524. Each conductive trace in the set of conductive traces 524 may be oriented parallel to the first axis 506 and electrically connected to a respective linear arrangement of photodiodes 504 defining a subset 512, 514, 516, 518, 520, 522 of photodiodes 504 in the different subsets of photodiodes 504.

The readout circuit 510 may also include an amplifier circuit 526 and a set of switches 528. Each switch in the set of switches 528 may electrically couple or decouple a respective conductive trace in the set of conductive traces 524 to the amplifier circuit 526. A control circuit 530 may be programmed or otherwise configured to operate the set of switches 528.

In some embodiments, the control circuit 530 may operate the set of switches 528 to sequentially couple each subset 512, 514, 516, 518, 520, 522 of photodiodes 504 to the amplifier circuit 526, while decoupling all other subsets 512, 514, 516, 518, 520, 522 of photodiodes 504 from the amplifier circuit 526, to read out a value for each subset 512, 514, 516, 518, 520, 522 of photodiodes 504.

In some embodiments, values may be read out for larger subsets of photodiodes 504. For example, and as shown, the control circuit 530 may operate the set of switches 528 to couple two subsets 516, 518 of photodiodes 504 to the amplifier circuit 526 at the same time, while decoupling all other subsets 512, 514, 520, 522 of photodiodes 504 from the amplifier circuit 526, to read out a value representing a sum of charges integrated by all of the photodiodes 504 in the two subsets 516, 518 of photodiodes 504. The control circuit 530 may then operate the set of switches 528 to couple a next two subsets 520, 522 of photodiodes 504 to the amplifier circuit 526, and so on. Alternatively, after coupling the two subsets 516, 518 of photodiodes 504 to the amplifier circuit 526, the control circuit 530 may open the switch coupling the subset 516 to the amplifier circuit 526, close the switch coupling the subset 520 to the amplifier circuit 526, and read out a value representing a sum of charges integrated by all of the photodiodes 504 in the two subsets 518, 520 of photodiodes 504—e.g., in a moving window approach that reads out values for overlapping combinations of different subsets (e.g., 512/514, 514/516, 516/518, 518/520, 520/522) of photodiodes 504.

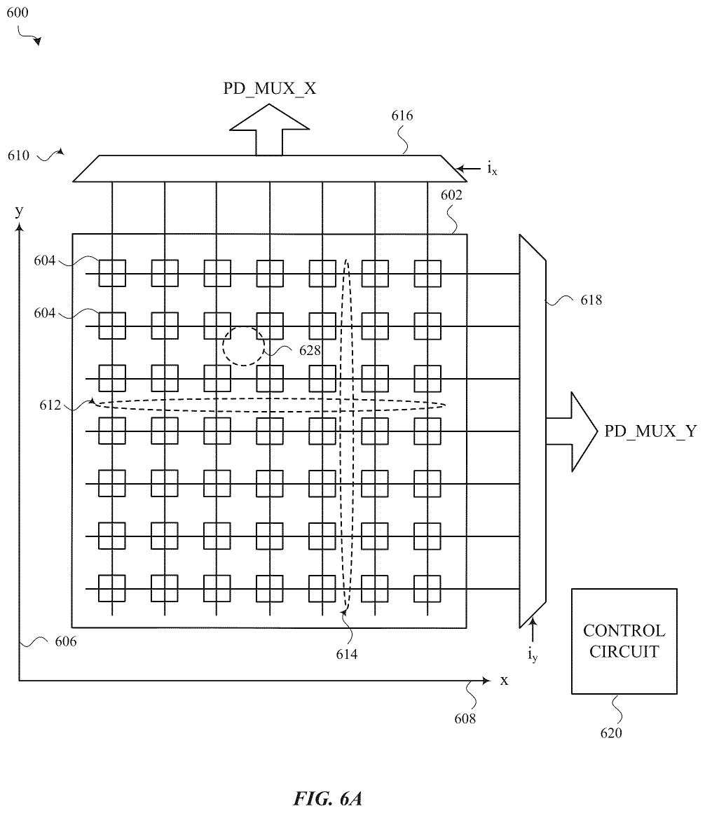

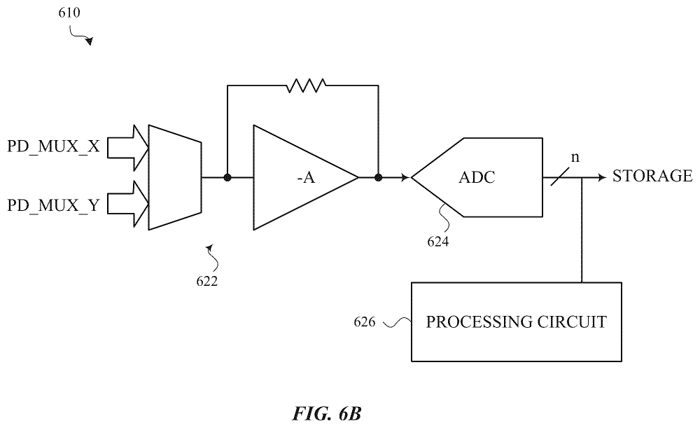

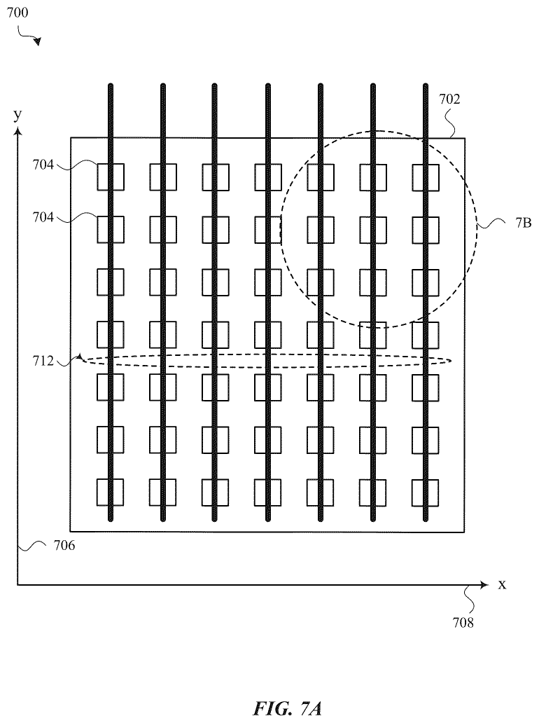

FIGS. 6A and 6B show another alternative example readout circuit for an optical sensor such as the optical sensor described with reference to FIGS. 3A and 3B. In particular, FIG. 6A shows an optical sensor 600 having an array of photodiodes 604 formed on a shared epitaxial structure 602, without guard structures between adjacent photodiodes 604. The array of photodiodes 604 may be disposed between a first axis 606 (e.g., a y-axis) and a second axis 608 (e.g., an x-axis, orthogonal to the y-axis).

FIGS. 6A and 6B show portions of a readout circuit 610 that may be electrically connected to the array of photodiodes 604. The readout circuit 610 may be operated to read out values for different individual photodiodes 604 (or alternatively, different subsets of photodiodes 604) in the array of photodiodes 604. The readout circuit 610 may include a first set of conductive traces 612 and a second set of conductive traces 614. Each conductive trace in the first set of conductive traces 612 may be oriented parallel to the first axis 606 and electrically connected to a respective linear arrangement of photodiodes (e.g., a column of photodiodes 604). Each conductive trace in the second set of conductive traces 614 may be oriented parallel to the second axis 608 and electrically connected to a respective linear arrangement of photodiodes (e.g., a row of photodiodes 604).

A first multiplexer 616 of the readout circuit 610 may have a set of inputs that is electrically connected to the first set of conductive traces 612. A second multiplexer 618 of the readout circuit 610 may have a set of inputs that is electrically connected to the second set of conductive traces 614. The first multiplexer 616 may have a control input ix, provided by a control circuit 620, that causes an addressed conductive trace in the first set of conductive traces 612 to be coupled to an output (PD_MUX_X) of the first multiplexer 616. The second multiplexer 618 may have a control input i_{y}, provided by the control circuit 620, that causes an addressed conductive trace in the second set of conductive traces 614 to be coupled to an output (PD_MUX_Y) of the second multiplexer 618. As shown in FIG. 6B, the outputs of the first and second multiplexers 616, 618 may be input to an amplifier circuit 622 that amplifies a voltage between PD_MUX_X and PD_MUX_Y. An analog output of the amplifier circuit 622 may be received by an analog-to-digital converter (ADC) 624 and converted to an n-bit digital value.

The values of iₓ and i_{y} may be cycled through different permutations of iₓ=1 to p and i_{y}=1 to q, to read out values for all of the photodiodes 604.

The n-bit digital value output by the ADC 624 may be routed to a storage circuit or, alternatively, to a processing circuit 626 that determines the x and y coordinates of a photodiode 604 associated with a highest illumination intensity. The relative illumination intensities of photodiodes 604 adjacent the photodiode 604 associated with the highest illumination intensity may be used to determine whether a light spot 628 is centered on a photodiode 604 or more to one side of the photodiode 604 (in x and y directions).

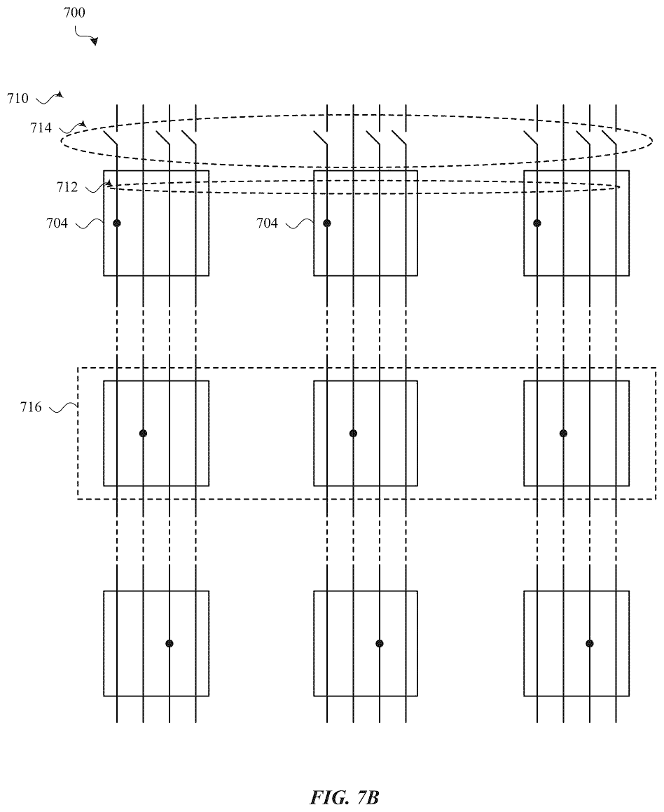

FIGS. 7A and 7B show another alternative example readout circuit for an optical sensor such as the optical sensor described with reference to FIGS. 3A and 3B. In particular, FIG. 7A shows an optical sensor 700 having an array of photodiodes 704 formed on a shared epitaxial structure 702, without guard structures between adjacent photodiodes 704, and FIG. 7B shows an enlarged portion of the optical sensor 700. The array of photodiodes 704 may be disposed between a first axis 706 (e.g., a y-axis) and a second axis 708 (e.g., an x-axis, orthogonal to the y-axis).

A readout circuit 710 that may be electrically connected to the array of photodiodes 704. The readout circuit 710 may be operated to read out values for different individual photodiodes 704 (or alternatively, different subsets (e.g., rows or columns) of photodiodes 704) in the array of photodiodes 704. The readout circuit 710 may include a set of conductive traces 712. Each conductive trace in the set of conductive traces 712 may be oriented parallel to the first axis 706 and electrically connect to a respective photodiode 704. Each conductive trace in the set of conductive traces 712 may be electrically connected to a dedicated or shared amplifier circuit via a respective switch in a set of switches 714, as described with reference to other figures. As shown in FIG. 7B, a subset of switches in the set of switches 714 may be closed, while other switches remain open, to read out values from a row 716 of photodiodes 704 connected to a subset of the conductive traces 712. Values for the photodiodes 704 in a row may be read out sequentially or in parallel, depending on the number of amplifier circuits that are available to perform the readout. In some embodiments, multiple switches associated with a single column of photodiodes 704 may be closed at the same time to sum the charges integrated by more than one photodiode 704 in a column during readout. In some embodiments, the set of switches 714 may also include switches that enable the charges integrated by photodiodes 704 in different rows, or the charges integrated by photodiodes 704 in different rows and columns, to be summed during readout.

In the embodiments described with reference to FIGS. 6A and 6B, and FIGS. 7A and 7B, an irradiation center or peak may be detected with respect to each of the optical sensor's first and second axes. The values obtained for photodiodes on all sides of the peak may be used to more precisely locate the irradiation center.

In some embodiments, the optical sensor described with FIGS. 6A and 6B, or FIGS. 7A and 7B, may be used to track both rotational and translational motion of a shaft, such as a shaft of the crown described with reference to FIG. 2.

In some embodiments, the optical sensor described with any of FIGS. 3A-7B may be associated with a readout circuit having channels associated with four different quadrants of an array of photodiodes. Such an arrangement may be used, for example, for displacement sensing, such as force sensing or atomic force microscopy.

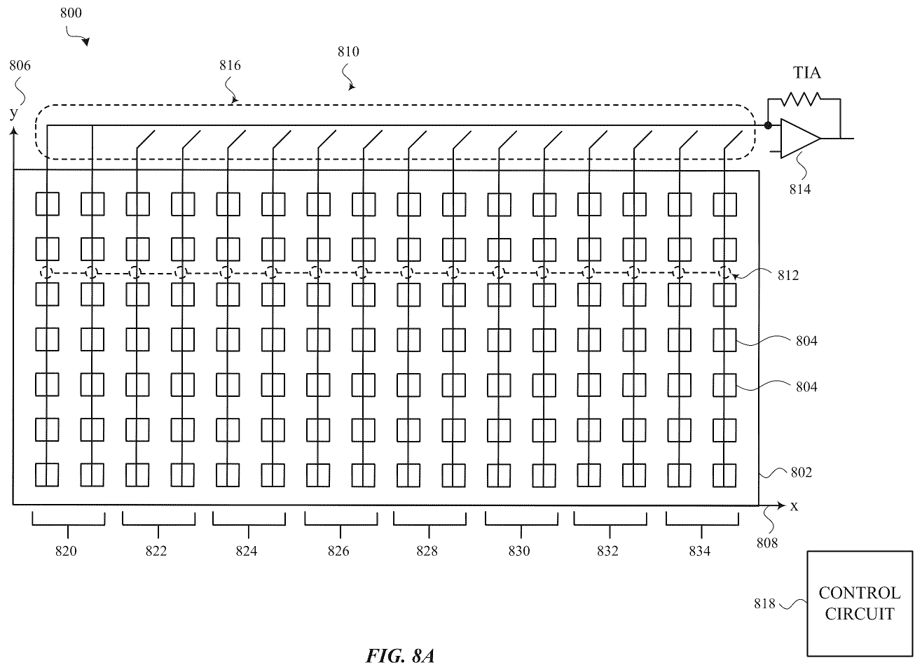

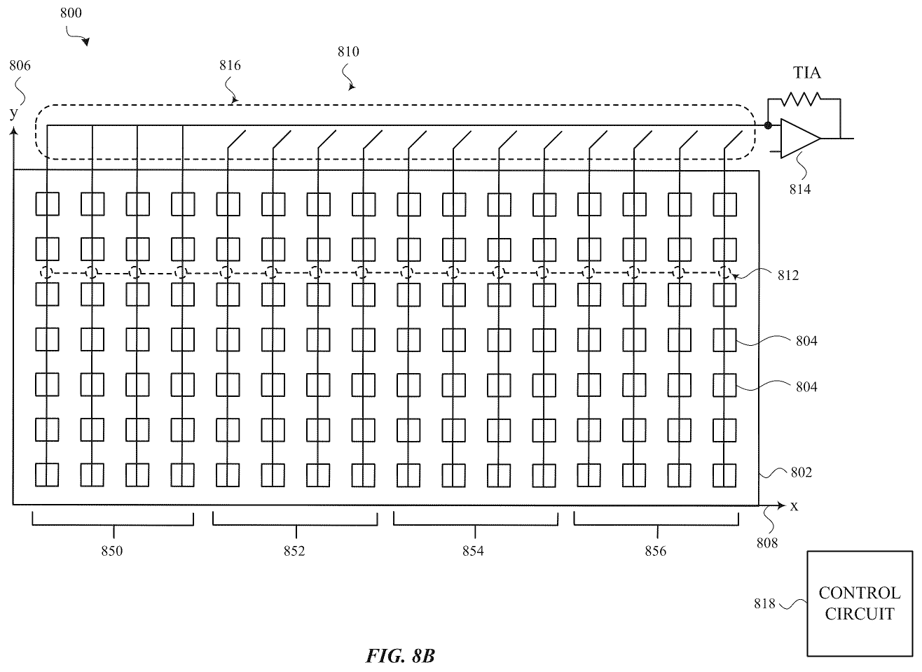

FIGS. 8A and 8B illustrate an example readout plan for an optical sensor such as the optical sensor described with reference to FIGS. 3A and 3B. In particular, FIGS. 8A and 8B show an optical sensor 800 having an array of photodiodes 804 formed on a shared epitaxial structure 802, without guard structures between adjacent photodiodes 804. The array of photodiodes 804 may be disposed between a first axis 806 (e.g., a y-axis) and a second axis 808 (e.g., an x-axis, orthogonal to the y-axis).

A readout circuit 810 may be electrically connected to the array of photodiodes 804. The readout circuit 810 may include a set of conductive traces 812 oriented parallel to the first axis 806. The set of conductive traces 812 may extend from within the array of photodiodes 804 to outside (e.g., adjacent or under) the array of photodiodes 804. For example, the conductive traces of the first set of conductive traces 812 may extend between individual ones or subsets of photodiodes 804 and an amplifier circuit 814, with the conductive traces in the set of conductive traces 812 being switchably coupled to the amplifier circuit 814 (e.g., by a set of switches 816). By way of example, multiple photodiodes 804 (a column of photodiodes 804) are electrically connected to each conductive trace in the set of conductive traces 812.

The set of switches 816 may be operated by a control circuit 818. As shown in FIG. 8A, and in a first mode of operation, the control circuit 818 may operate the set of switches 816 so that only a leftmost pair of conductive traces 812 is coupled to the amplifier circuit 814, and the control circuit 818 may cause a first value for a first channel 820 to be read out of the optical sensor 800 via the amplifier circuit 814. Subsequently, the control circuit 818 may operate the set of switches 816 so that only a next pair of conductive traces 812 is coupled to the amplifier circuit 814, and the control circuit 818 may cause a second value for a second channel 822 to be read out of the optical sensor 800 via the amplifier circuit 814, and so on for subsequent channels 824, 826, 828, 830, 832, and 834.

As shown in FIG. 8B, and in a second mode of operation, the control circuit 818 may operate the set of switches 816 so that only a leftmost set of four conductive traces 812 is coupled to the amplifier circuit 814, and the control circuit 818 may cause a first value for a first channel 850 to be read out of the optical sensor 800 via the amplifier circuit 814. Subsequently, the control circuit 818 may operate the set of switches 816 so that only a next set of four conductive traces 812 is coupled to the amplifier circuit 814, and the control circuit may cause a second value for a second channel 852 to be read out of the optical sensor 800 via the amplifier circuit 814, and so on for subsequent channels 854, and 856.

The control circuit 818 may also operate the set of switches 816 in accordance with other modes of operation.

In some embodiments, the optical sensor 800 may be used to track the rotation of a shaft, such as the shaft of the crown described with reference to FIG. 2. In such embodiments, and at a first time (or times), the control circuit 818 may use a low (or relatively lower) frame rate at a speed of rotation that is less than a threshold speed of rotation. The low frame rate may be associated with a greater number of channels, such as the eight channels defined in the first mode of operation described with reference to FIG. 8A. A low frame rate may maximize user experience and performance for the most sensitive (or granular) rotation tracking needs. Alternatively, at a second time (or times), the control circuit 818 may use a high (or relatively higher) frame rate at a speed of rotation that is equal to or greater than the threshold speed of rotation. The high frame rate may be associated with a lower number of channels, such as the four channels defined in the second mode of operation described with reference to FIG. 8B. A lower number of channels enables a faster readout speed for high-speed light spot or light stripe tracking (e.g., the tracking of light reflected off features of a crown that is being rotated at a fast speed of rotation.

In alternative embodiments, conductive traces may electrically connect individual ones of the photodiodes 804 to different conductive traces; or alternating ones of the photodiodes 804 may be electrically connected to first or second conductive traces associated with a single column of photodiodes 804; or rows of photodiodes 804 may be electrically connected to different conductive traces; or photodiodes may be electrically connected to a set of switches in other ways. In each of these embodiments, a control circuit may couple or decouple conductive traces to an amplifier circuit in accordance with different modes of operation. In some embodiments, different modes of operation may be associated with different numbers of channels. In some embodiments, different modes of operation may be associated with different numbers of photodiodes per channel. In some embodiments, different modes of operation may be associated with different distributions or spacings of photodiodes. In some embodiments, more than one variable may vary between different modes of operation.

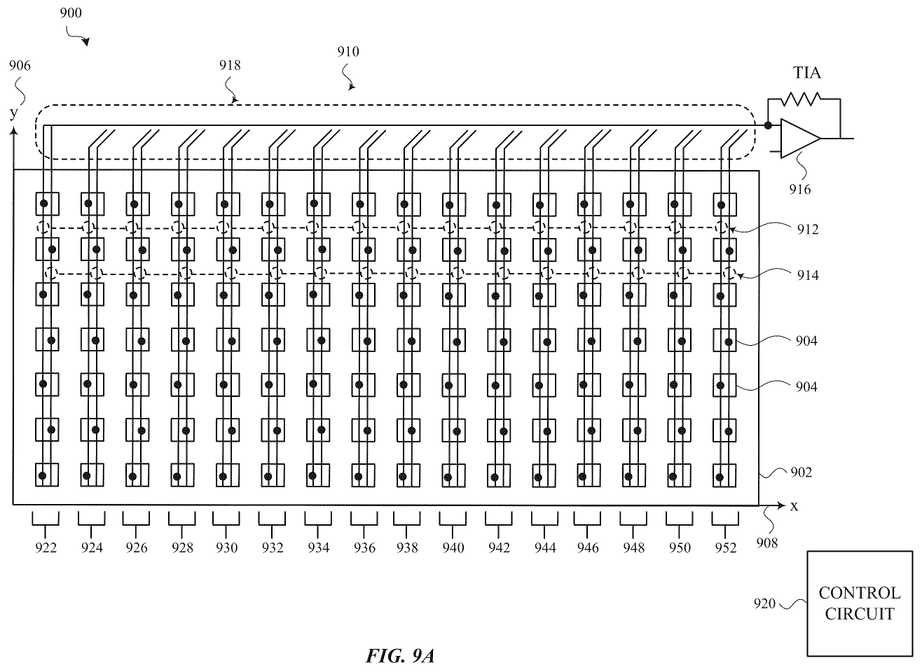

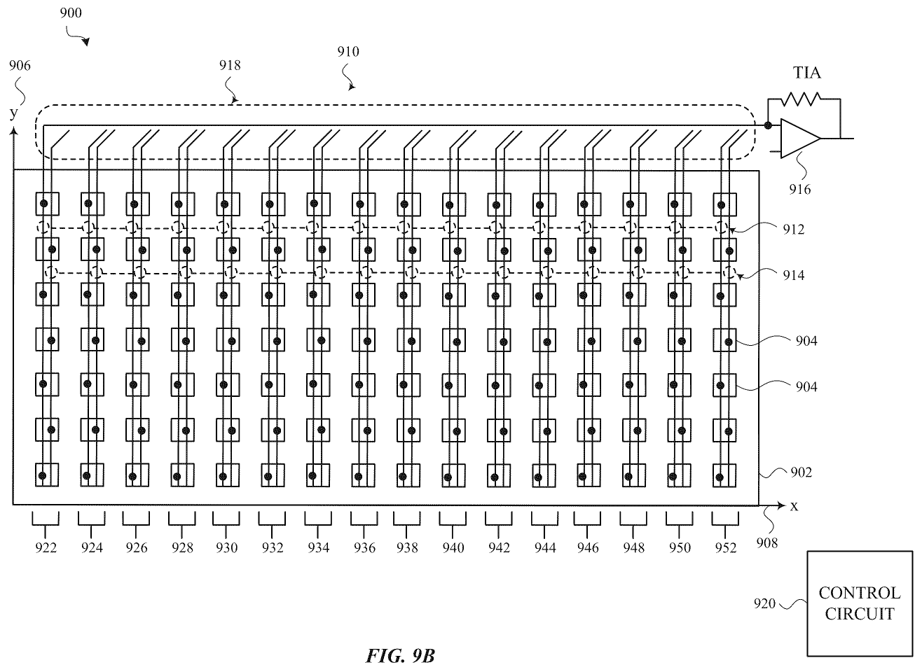

FIGS. 9A and 9B illustrate another example readout plan for an optical sensor such as the optical sensor of FIGS. 3A and 3B. In particular, FIGS. 9A and 9B show an optical sensor 900 having an array of photodiodes 904 formed on a shared epitaxial structure 902, without guard structures between adjacent photodiodes 904. The array of photodiodes 904 may be disposed between a first axis 906 (e.g., a y-axis) and a second axis 908 (e.g., an x-axis, orthogonal to the y-axis).

A readout circuit 910 may be electrically connected to the array of photodiodes 904. The readout circuit 910 may include first and second sets of conductive traces 912, 914 oriented parallel to the first axis 906. Each of the first and second sets of conductive traces 912, 914 may extend from within the array of photodiodes 904 to outside (e.g., adjacent or under) the array of photodiodes 904. The conductive traces of the first and second sets of conductive traces 912, 914 may extend between different subsets of photodiodes 904 and an amplifier circuit 916, with the conductive traces in the first and second sets of conductive traces 912, 914 being switchably coupled to the amplifier circuit 916 (e.g., by a set of switches 918). By way of example, a first subset of every other photodiode 904 in a column of photodiodes 904 is electrically connected to a first conductive trace of the set of conductive traces 912, associated with the column, and a second subset of every other photodiode 904 in the column of photodiodes 904 is electrically connected to a second conductive trace of the set of conductive traces 914, associated with the column.

The set of switches 918 may be operated by a control circuit 920. As shown in FIG. 9A, and in a first mode of operation, the control circuit 920 may operate the set of switches 918 so that the conductive traces 912, 914 associated with a first column are coupled to the amplifier circuit 916 at the same time, and the control circuit 920 may cause a first value for a first channel 922 to be read out of the optical sensor 900 via the amplifier circuit 916. Subsequently, the control circuit 920 may operate the set of switches 918 so that conductive traces 912, 914 associated with a second column are coupled to the amplifier circuit 916 at the same time, and the control circuit 920 may cause a second value for a second channel 924 to be read out of the optical sensor 900 via the amplifier circuit 916, and so on for subsequent channels 926, 928, 930, 932, 934, 936, 938, 940, 942, 944, 946, 948, 950, and 952.

As shown in FIG. 9B, and in a second mode of operation, the control circuit 920 may operate the set of switches 918 so that only one of the conductive traces 912 associated with the first column is coupled to the amplifier circuit 916, and the control circuit 920 may cause a first value for the first channel 922 to be read out of the optical sensor 900 via the amplifier circuit 916. Subsequently, the control circuit 920 may operate the set of switches 918 so that only one of the conductive traces 912 associated with the second column is coupled to the amplifier circuit 916, and the control circuit 920 may cause a second value for the second channel 924 to be read out of the optical sensor 900 via the amplifier circuit 916, and so on for subsequent channels 926, 928, 930, 932, 934, 936, 938, 940, 942, 944, 946, 948, 950, and 952.

The control circuit 920 may also operate the set of switches 918 in accordance with other modes of operation.

In some embodiments, the first and second modes of operation of the optical sensor 900 may be used to vary the number of photodiodes per channel without varying the number of channels. Stated differently, the first mode of operation may be associated with a first density of photodiodes, and the second mode of operation may be associated with a second density of photodiodes, with the second density being different from the first density. Under normal operating conditions, the first density may be appropriate, and all of the photodiodes 904 may be employed. However, if the control circuit 920 or a processing circuit detects saturation within a channel, the control circuit 920 or processing circuit may switch to the second mode of operation, in which a lower density of photodiodes 904 is employed.

In some embodiments, the first and second modes of operation of the optical sensor 900 may be used to detect, or to avoid interference from, a flickering light source (e.g., by appropriately timing the sample rate of the photodiodes 904 that are electrically connected to the first set of conductive traces 912 versus the photodiodes 904 that are electrically connected to the second set of conductive traces 914.

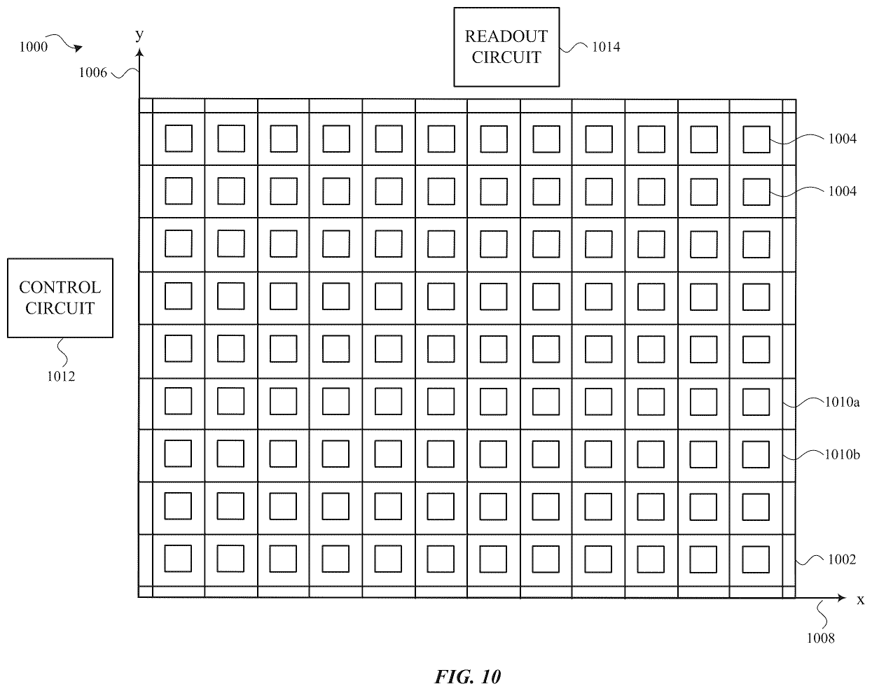

FIG. 10 shows a plan view of another example optical sensor 1000. The optical sensor 1000 may be used, for example, in the electronic device described with reference to FIGS. 1A and 1B, as a sensor of a biological parameter, or as an ambient light sensor, or in other applications.

The optical sensor 1000 includes an epitaxial structure 1002 that is shared by an array of photodiodes 1004. The array of photodiodes 1004 may be disposed between a first axis 1006 (e.g., a y-axis) and a second axis 1008 (e.g., an x-axis, orthogonal to the y-axis). In alternative embodiments, the photodiodes 1004 may be arranged in different ways, such as in concentric rings or pseudo-randomly. The photodiodes 1004 may be constructed using various materials, and may be constructed in accordance with various techniques, to be sensitive to one or more types of light. In some examples, the photodiodes 1004 may be sensitive to a range of wavelengths that encompasses different types of light.

The array of photodiodes 1004 is characterized by an absence of guard structures between adjacent photodiodes 1004.

Various types of readout circuits may be electrically connected to the array of photodiodes 1004, including any of the readout circuits described herein.

An array of filter elements 1010 may be disposed over the array of photodiodes 1004. The array of filter elements 1010 may include at least two different types of filter element 1010a, 1010b, and at least two different photodiodes 1004 in the array of photodiodes 1004 may be disposed under respective different types of filter element 1010a, 1010b in the array of filter elements 1010. In some embodiments, the array of filter elements 1010 may be different optical band pass filters, or elements of a linearly chirped band pass filter.

In some embodiments, a control circuit 1012 associated with a readout circuit 1014 of the optical sensor 1000 may form or tune a spectral sensor by electrically connecting photodiodes 1004 disposed under filter elements 1010 of one or more particular type to the readout circuit 1014. For example, the control circuit 1012 may configure the readout circuit 1014 in one or more modes of operation, in which a first mode of operation has a first spectral response and a second mode of operation has a second spectral response, with the second spectral response being different from the first spectral response. Alternatively, a mode of operation may be configured to have a desired spectral response, such as 100% of the photodiodes 1004 disposed under red filter elements and 20% of the photodiodes 1004 disposed under green filter elements.

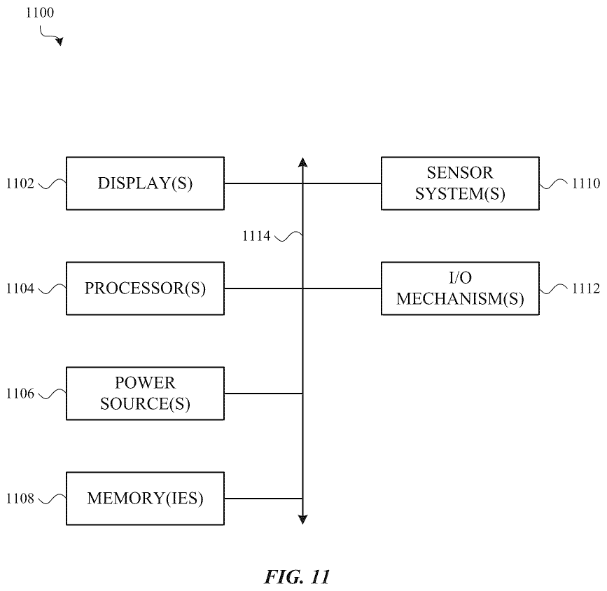

FIG. 11 shows a sample electrical block diagram of an electronic device 1100, which electronic device 1100 may in some cases be the electronic device described with reference to FIGS. 1A and 1B, or any of the other devices described herein. The electronic device 1100 may include an optical sensor for sensing translational and/or rotational movements of an input device, as described with reference to any of FIGS. 1A-10. The electronic device 1100 may optionally include an electronic display 1102 (e.g., a light-emitting display), a processor 1104, a power source 1106, a memory 1108 or storage device, a sensor system 1110, and/or an input/output (I/O) mechanism 1112 (e.g., an input/output device, input/output port, or haptic input/output interface). The processor 1104 may control some or all of the operations of the electronic device 1100. The processor 1104 may communicate, either directly or indirectly, with some or all of the other components of the electronic device 1100. For example, a system bus or other communication mechanism 1114 can provide communication between the electronic display 1102, the processor 1104, the power source 1106, the memory 1108, the sensor system 1110, and the I/O mechanism 1112.

The processor 1104 may be implemented as any electronic device capable of processing, receiving, or transmitting data or instructions, whether such data or instructions is in the form of software or firmware or otherwise encoded. For example, the processor 1104 may include a microprocessor, a central processing unit (CPU), an application-specific integrated circuit (ASIC), a digital signal processor (DSP), a control circuit, or a combination of such devices. As described herein, the term “processor” is meant to encompass a single processor or processing unit, multiple processors, multiple processing units, or other suitably configured computing element or elements. In some cases, the processor 1104 may provide part or all of the processing system or processor described herein.

It should be noted that the components of the electronic device 1100 can be controlled by multiple processors. For example, select components of the electronic device 1100 (e.g., the sensor system 1110) may be controlled by a first processor and other components of the electronic device 1100 (e.g., the electronic display 1102) may be controlled by a second processor, where the first and second processors may or may not be in communication with each other.

The power source 1106 can be implemented with any device capable of providing energy to the electronic device 1100. For example, the power source 1106 may include one or more batteries or rechargeable batteries. Additionally, or alternatively, the power source 1106 may include a power connector or power cord that connects the electronic device 1100 to another power source, such as a wall outlet. The power source 1106 may also include a wireless charging circuit.

The memory 1108 may store electronic data that can be used by the electronic device 1100. For example, the memory 1108 may store electrical data or content such as, for example, audio and video files, documents and applications, device settings and user preferences, timing signals, control signals, instructions, and/or data structures or databases. The memory 1108 may include any type of memory. By way of example only, the memory 1108 may include random access memory, read-only memory, Flash memory, removable memory, other types of storage elements, or combinations of such memory types.

The electronic device 1100 may also include one or more sensor systems 1110 positioned almost anywhere on the electronic device 1100. The sensor system(s) 1110 may be configured to sense one or more types of parameters, such as but not limited to: vibration, light, touch, force, heat, movement, relative motion, biometric data (e.g., biological parameters) of a user, air quality, proximity, position, connectedness, surface quality, and so on. By way of example, the sensor system(s) 1110 may include a heat sensor, a position sensor, a light or optical sensor, an accelerometer, a pressure transducer, a gyroscope, a magnetometer, a health monitoring sensor, and an air quality sensor, and so on. Additionally, the one or more sensor systems 1110 may utilize any suitable sensing technology, including, but not limited to, interferometric, magnetic, capacitive, ultrasonic, resistive, optical, acoustic, piezoelectric, or thermal technologies.

The I/O mechanism 1112 may transmit or receive data from a user or another electronic device. The I/O mechanism 1112 may include the electronic display 1102, a touch sensing input surface, a crown (e.g., a crown associated with an assembly for optically sensing translational and rotational movements of an input device, as described with any of FIGS. 1A-9), one or more buttons (e.g., a graphical user interface “home” button), one or more cameras (including an under-display camera), one or more microphones or speakers, one or more ports such as a microphone port, and/or a keyboard. Additionally, or alternatively, the I/O mechanism 1112 may transmit electronic signals via a communications interface, such as a wireless, wired, and/or optical communications interface. Examples of wireless and wired communications interfaces include, but are not limited to, cellular and Wi-Fi communications interfaces.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. An electronic device, comprising:
a shared epitaxial structure;
an array of photodiodes formed in the shared epitaxial structure, the array of photodiodes disposed between a first axis and a second axis, the second axis orthogonal to the first axis, the array of photodiodes having an absence of guard structures between adjacent photodiodes; and
a readout circuit electrically connected to the array of photodiodes and operable to read out values for different photodiodes or different subsets of photodiodes in the array of photodiodes.

2. The electronic device of claim 1, wherein the readout circuit is operable to read out values for different subsets of photodiodes extending parallel to the first axis.

3. The electronic device of claim 1, wherein:
the readout circuit is operable to read out values for,
different subsets of photodiodes extending parallel to the first axis; and
different subsets of photodiodes extending parallel to the second axis.

4. The electronic device of claim 1, wherein:
the readout circuit includes,
a first set of conductive traces oriented parallel to the first axis and extending from within the array of photodiodes to outside the array of photodiodes; and
a second set of conductive traces oriented parallel to the second axis and electrically connecting each photodiode in the array of photodiodes to a particular conductive trace in the first set of conductive traces.

5. The electronic device of claim 4, further comprising a set of dummy conductive traces, each dummy conductive trace oriented parallel to the second axis, and each dummy conductive trace disposed inline with one or more conductive traces in the second set of conductive traces.

6. The electronic device of claim 4, wherein:
the readout circuit is operable to read out values for different subsets of photodiodes in the array of photodiodes;
the first set of conductive traces comprises different groups of conductive traces; and
each group of conductive traces of the different groups of conductive traces is disposed between respective different subsets of the different subsets of photodiodes.

7. The electronic device of claim 1, wherein:
the readout circuit is operable to read out values for different subsets of photodiodes in the array of photodiodes; and
the readout circuit includes a set of conductive traces, each conductive trace in the set of conductive traces oriented parallel to the first axis and electrically connected to a respective linear arrangement of photodiodes defining a subset of photodiodes in the different subsets of photodiodes.

8. The electronic device of claim 7, wherein:
the readout circuit includes,
an amplifier circuit; and
a set of switches, each switch in the set of switches electrically coupling or decoupling a conductive trace in the set of conductive traces to the amplifier circuit.

9. The electronic device of claim 1, wherein:
the readout circuit includes,
a set of conductive traces, each conductive trace in the set of conductive traces electrically connected to a respective photodiode of the different photodiodes or to a respective subset of photodiodes in the different subsets of photodiodes;
an amplifier circuit; and
a set of switches, each switch in the set of switches electrically coupling or decoupling a respective conductive trace in the set of conductive traces to the amplifier circuit; and
the electronic device further comprises a control circuit configured to operate the set of switches to sequentially read out values for each photodiode in the different photodiodes or each subset of photodiodes in the different subsets of photodiodes.

10. The electronic device of claim 1, wherein:
the readout circuit includes,
a set of conductive traces, each conductive trace in the set of conductive traces electrically connected to a respective photodiode of the different photodiodes or to a respective subset of photodiodes in the different subsets of photodiodes;
an amplifier circuit; and
a set of switches, each switch in the set of switches electrically coupling or decoupling a respective conductive trace in the set of conductive traces to the amplifier circuit; and
the electronic device further comprises a control circuit configured to operate the set of switches to sequentially read out values for overlapping combinations of photodiodes in the different photodiodes or overlapping combinations of subsets of photodiodes in the different subsets of photodiodes.

11. An electronic device, comprising:
a shared epitaxial structure;
an array of photodiodes formed in the shared epitaxial structure, the array of photodiodes having an absence of guard structures between adjacent photodiodes;
a readout circuit electrically connected to the array of photodiodes and operable to read out values for a set of channels defined by the photodiodes in the array of photodiodes; and
a control circuit operable to configure the readout circuit in one or more modes of operation, each mode of operation in the one or more modes of operation defining at least one of,
a number of channels in the set of channels; or
a number of photodiodes per channel in the set of channels.

12. The electronic device of claim 11, wherein the control circuit is operable to configure the readout circuit in at least a first mode of operation at a first time and a second mode of operation at a second time, the second mode of operation different from the first mode of operation.

13. The electronic device of claim 11, wherein the control circuit is operable to configure the readout circuit in at least a first mode of operation having a first density of photodiodes and a second mode of operation having a second density of photodiodes, the second density of photodiodes different from the first density of photodiodes.

14. The electronic device of claim 11, further comprising:
an array of filter elements disposed over the array of photodiodes, the array of filter elements including at least two different types of filter element, and at least two different photodiodes in the array of photodiodes disposed under respective different types of filter element in the array of filter elements.

15. The electronic device of claim 14, wherein the one or more modes of operation of the readout circuit include a first mode of operation having a first spectral response and a second mode of operation having a second spectral response, the second spectral response different from the first spectral response.

16. An electronic device, comprising:
a housing;
a crown having a shaft, the shaft extending through the housing and having a set of features disposed around the shaft;
a light source positioned within the housing and configured to emit light toward the shaft; and
an optical sensor positioned within the housing and configured to receive reflections of the emitted light from the set of features, the optical sensor including,
a shared epitaxial structure; and
an array of photodiodes formed in the shared epitaxial structure and having an absence of guard structures between adjacent photodiodes.

17. The electronic device of claim 16, further comprising:
a readout circuit electrically connected to the array of photodiodes and operable to read out values for a set of channels defined by the photodiodes in the array of photodiodes.

18. The electronic device of claim 17, wherein:
each channel in the set of channels includes multiple photodiodes; and
different channels in the set of channels have different axes parallel to an axis of rotation of the shaft.

19. The electronic device of claim 17, further comprising:
a control circuit operable to configure the readout circuit in one or more modes of operation, the one or more modes of operation defining,
a first number of channels having different axes parallel to an axis of rotation of the shaft; and
a second number of channels having different axes perpendicular to the axis of rotation of the shaft.

20. The electronic device of claim 17, wherein, in at least one mode of operation, each channel in the set of channels is defined by a respective photodiode in the array of photodiodes.
